(19) United States
(12) Patent Application Publication
(10) Pub. No.: US 2022/0416462 A1
(43) Pub. Date: Dec. 29, 2022

(54) SPRING CONNECTOR

(71) Applicant: YOKOWO CO., LTD., Kita-ku, Tokyo (JP)

(72) Inventor: Masashi HIRANO, Tomioka-shi, Gunma (JP)

(73) Assignee: YOKOWO CO., LTD., Kita-ku, Tokyo (JP)

(21) Appl. No.: 17/780,526

(22) PCT Filed: Nov. 11, 2020
(86) PCT No.: PCT/JP2020/042018

§ 371 Date: May 27, 2022

(30) Foreign Application Priority Data
Nov. 29, 2019 (JP) 2019-216390

(51) Int. Cl. H01R 13/24

(52) U.S. Cl. CPC H01R 13/2421; H01R 13/2492

(57) ABSTRACT

A spring connector includes: a conductive tube; a movable pin that has a tip end portion protruding from an opening of the tube along an axial direction of the tube; a movable body that is provided inside the tube and that has one end portion in contact with a rear end portion of the movable pin; and a spring that is provided inside the tube and that is configured to urge another end portion of the movable body in a direction in which the movable pin protrudes. The other end portion of the movable body is an inclined surface inclined with respect to the axial direction, and at least one of the one end portion of the movable body and the rear end portion of the movable pin includes a convex portion.

### TECHNICAL FIELD

The present invention relates to a spring connector.

### BACKGROUND ART

A spring connector of the related art will be described with reference to the drawings. FIG. 9 is a view showing an example of a configuration of a spring connector 100 of the related art, and is a longitudinal sectional view showing an internal structure by cutting out a tube 30. As shown in FIG. 9, the spring connector 100 includes a movable pin 50 that protrudes from one open end side of the tube 30. The movable pin 50 is urged in a protruding direction by a spring 80 in the tube 30.

There are various shapes of a tip end of the movable pin, and a shape of the tip end suitable for a shape of an object to be contacted can be selected. For example, as shown in FIG. 9, a tip end portion 501 having a hemispherical shape can be selected. A rear end portion of the movable pin 50 forms an inclined surface 503 inclined with respect to an axial direction of the tube 30. Therefore, when the tip end portion 501 of the movable pin 50 is brought into contact with an object 90 to be contacted and the movable pin 50 is pushed into the tube 30 during use, a reaction force of the spring 80 is applied to the inclined surface 503, and a force in a direction perpendicular to the axial direction of the tube 30 acts on the movable pin 50. Then, a part of a side surface of the movable pin 50 is pressed against an inner wall of the tube 30 (arrow A11). Since a contact surface of the object 90 to be contacted is a plane, a center axis of the movable pin 50 is inclined (arrow A13) by the tip end portion 501 rolling on the contact surface of the object 90 to be contacted, and the other part of the side surface of the movable pin 50 is pressed against the inner wall of the tube 30 (arrow A15). This ensures contact and conduction between the movable pin 50 and the tube 30.

In the spring connector described in Patent Literature 1, the movable pin is inclined at the time of pushing due to eccentricity of a hole of a tube opening portion, and the rear end portion of the movable pin is formed into a conical surface so as to be conductive.

On the other hand, there has been known a movable pin in which a plurality of protrusions are provided on a tip end portion for the purpose of removing a coating film formed on a surface of an object to be contacted or the like, and a shape of a tip end is a protruding end shape. FIG. 10 is a longitudinal sectional view showing a spring connector 100a in which the movable pin 50 of FIG. 9 is replaced with a movable pin 50a having a protruding end shape at a tip end portion 501a. In this configuration, each protrusion of the tip end portion 501a abuts against the object 90 to be contacted during use. According to the movable pin 50a of FIG. 10, the protrusions of the tip end portion 501a have a positional relationship in which a virtual plane can be defined by connecting tip ends of the protrusions.

### CITATION LIST

### Patent Literature

Patent Literature 1: JP-A-2006-73287

### SUMMARY OF INVENTION

### Technical Problem

In the spring connector of the related art shown in FIG. 10, when the tip end portion 501a of the movable pin 50a comes into contact with the contact surface of the object 90 to be contacted, the center axis of the movable pin 50a is aligned with a center axis of the tube 30, and the movable pin 50a is pushed into the tube 30 while maintaining this state. Therefore, the contact between the tube 30 and the movable pin 50a becomes unstable, which may lead to an increase in a contact resistance between the tube 30 and the movable pin 50a due to a decrease in an amount of electric current supplied between the tube 30 and the movable pin 50a, burnout of the spring 80 due to an increase in the amount of electric current supplied through the spring 80, and the like. As a result, the spring connector may be deteriorated.

An example of the object of the present invention is to provide a technique capable of improving contact stability in a spring connector regardless of a shape of a tip end of a movable pin.

### Solution to Problem

According to an aspect of the present invention, a spring connector includes: a conductive tube; a movable pin that has a tip end portion protruding from an opening of the tube along an axial direction of the tube; a movable body that is provided inside the tube and that has one end portion in contact with a rear end portion of the movable pin; and a spring that is provided inside the tube and that is configured to urge another end portion of the movable body in a direction in which the movable pin protrudes. The other end portion of the movable body is an inclined surface inclined with respect to the axial direction, and at least one of the one end portion of the movable body and the rear end portion of the movable pin includes a convex portion.

According to this aspect, the movable body is interposed between the movable pin and the spring, the one end portion of the movable body is brought into contact with the rear end portion of the movable pin, and the other end portion of the movable body is urged by the spring in the direction in which the movable pin protrudes (protruding direction). The other end portion of the movable body is the inclined surface inclined with respect to the axial direction of the tube, and at least one of the one end portion of the movable body and the rear end portion of the movable pin has the convex portion. According to this, the movable body is inclined inside the tube, and a side surface of the movable body is pressed against an inner wall of the tube. Therefore, the movable body and the tube can be reliably brought into contact with each other during use, and stable electrical connection between the movable pin and the tube can be realized via the movable body. It is possible to provide the technique capable of improving the contact stability in the spring connector regardless of the shape of the tip end of the movable pin.

### BRIEF DESCRIPTION OF DRAWINGS

FIG. 1 is a longitudinal sectional view showing a configuration example of a spring connector in a state in which a movable pin protrudes.

FIG. 2 is a longitudinal sectional view showing a configuration example of the spring connector in a state where the movable pin is moved backward.

FIG. 3 is a perspective view showing a protruding end shape of a tip end portion of the movable pin.

FIG. 4 is a perspective view showing a modified example of the protruding end shape of the tip end portion.

FIG. 5 is a perspective view showing other modified example of the protruding end shape of the tip end portion.

FIG. 6 is a longitudinal sectional view showing a modified example of the spring connector.

FIG. 7 is a longitudinal sectional view showing other modified example of the spring connector.

FIG. 8 is a longitudinal sectional view showing still other modified example of the spring connector.

FIG. 9 is a view showing a configuration example of a spring connector of related art.

FIG. 10 is a longitudinal sectional view showing a spring connector in which a tip end portion of a movable pin in FIG. 9 is formed into a protruding end shape.

### DESCRIPTION OF EMBODIMENTS

A preferred embodiment of the present invention will be described. The present invention is not limited to the embodiments described below, and modes to which the present invention can be applied are not limited to the following embodiments. In the drawings, the same components are denoted by the same reference numerals.

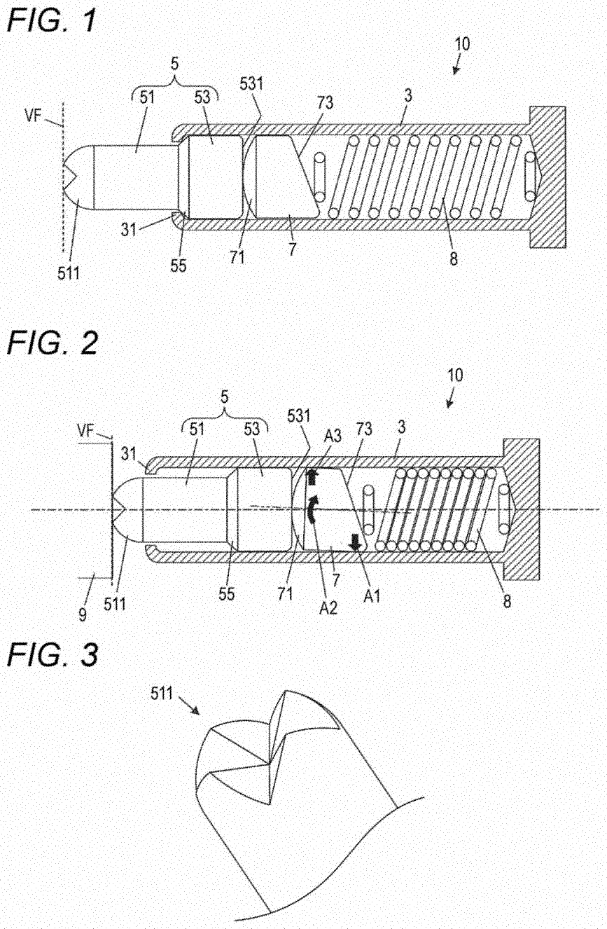

FIGS. 1 and 2 are longitudinal sectional views showing a configuration example of a spring connector 10 according to the present embodiment, in which FIG. 1 shows a state in which a movable pin 5 protrudes, and FIG. 2 shows a state in which a tip end portion 511 of the movable pin 5 is pushed and moved backward into a tube 3. As shown in FIGS. 1 and 2, the spring connector 10 includes the tube 3 having an opening at one end, the movable pin 5 having the tip end portion 511 protruding from the opening of the tube 3 along an axial direction of the tube 3, a movable body 7 provided inside the tube 3 and having one end in contact with a rear end portion of the movable pin 5, and a spring 8 provided in the tube 3 and urging the other end portion of the movable body 7 in a direction in which the movable pin 5 protrudes (protruding direction).

The tube 3 is a cylindrical body made of a conductive material (for example, copper, a copper alloy, or the like), and holds the movable pin 5 such that the movable pin 5 is slidable in the axial direction on one open end side. An open end of the tube 3 is bent inward by caulking to form a locking portion 31, which prevents the movable pin 5 from coming off.

The movable pin 5 is made of a conductive material (for example, copper, a copper alloy, or the like). The movable pin 5 includes a small diameter portion 51 and a large diameter portion 53 having a larger diameter than the small diameter portion 51, and the tip end portion 511 that is a tip end of the small diameter portion 51 serves as a contact portion that comes into contact with a terminal, which is an object 9 to be contacted (see FIG. 2). The small diameter portion 51 and the large diameter portion 53 are connected to each other in a stepped manner, and a tapered step surface 55 between the small diameter portion 51 and the large diameter portion 53 abuts against the locking portion 31 of the tube 3, thereby preventing the movable pin 5 from coming off the tube 3. Therefore, the large diameter portion 53 is located inside the tube 3 even in a state where the small diameter portion 51 protrudes from the tube 3.

In the present embodiment, a rear end of the large diameter portion 53, which is the rear end portion of the movable pin 5, is a flat planar portion 531.

On the other hand, the tip end portion 511 of the movable pin 5 has a protruding end shape forming a virtual contact surface VF that comes into surface contact with the object 9 to be contacted. FIG. 3 is an enlarged perspective view showing the protruding end shape of the tip end portion 511 of the movable pin 5. In the present embodiment, as shown in FIG. 3, the tip end portion 511 has a protruding end shape formed by four protrusions. Therefore, as shown in FIGS. 1 and 2, a surface determined by vertices of the protrusions is the contact surface VF that comes into surface contact with the object 9 to be contacted.

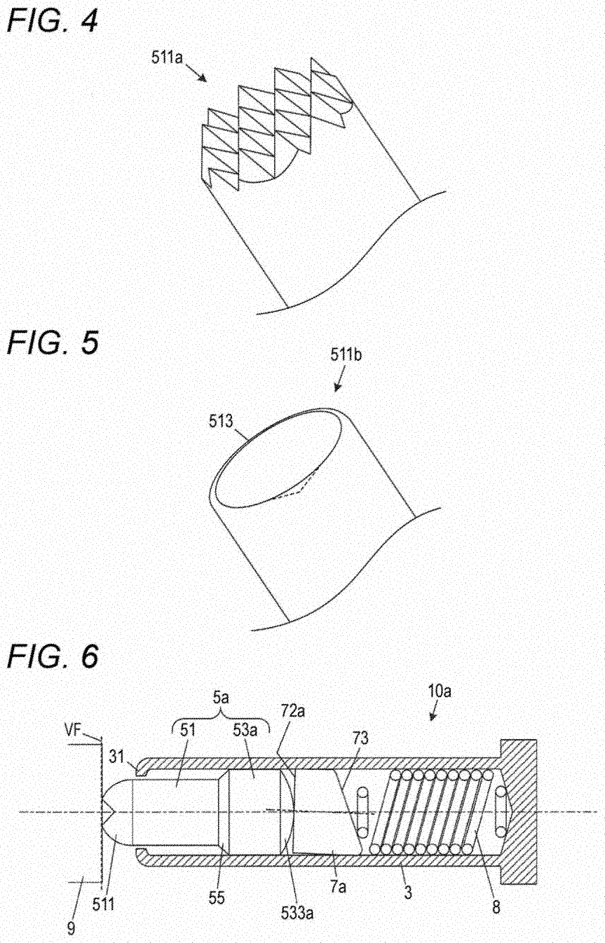

When a shape of a tip end of the movable pin 5 is the protruding end shape, the shape is not limited to the four protrusions shown in FIG. 3, and may be any shape as long as a contact surface can be formed. As long as the protrusion is provided at the tip end portion, the number of the protrusions may be two, three, or five or more. For example, as in a tip end portion 511a shown in FIG. 4, the tip end portion may be formed into a protruding end shape having a large number of protrusions.

The protruding end shape of the tip end portion may be a line-shaped edge. For example, as shown in FIG. 5, a tip end portion 511b of the movable pin may have a conical shape or a curved shape (not shown) that is convex in a direction (backward direction) opposite to the protruding direction as a concave portion, and an edge portion of the concave portion may be provided as an edge 513.

The movable body 7 is made of a conductive material (for example, copper, a copper alloy, or the like). One end portion of the movable body 7 on a side where the movable body 7 comes into contact with the rear end portion of the movable pin 5 forms a convex portion 71. The convex portion 71 may have, for example, a curved shape such as an arched rotating body shape shown in FIG. 1. In other case, the curved shape of the convex portion 71 may be a conical shape or the like. On the other hand, the other end portion of the movable body 7 on the side where the movable body 7 comes into contact with the spring 8 forms an inclined surface 73 inclined with respect to the axial direction of the tube 3.

The spring 8 is, for example, a coil spring that can be made of a piano wire or a stainless steel wire. Alternatively, the spring 8 may be made of an insulating material or may be covered with an insulating film.

With this configuration, contact and conduction between the movable body 7 and the tube 3 are ensured. When the object 9 to be contacted is pressed against the tip end portion 511 during use, as shown in FIG. 2, each protrusion of the tip end portion 511 abuts against the object 9 to be contacted, and the tip end portion 511 comes into surface contact with the object 9 to be contacted at the contact surface VF.

The movable pin 5 is inserted into the tube 3 such that the center axis of the movable pin 5 extends along the axial direction of the tube 3. Therefore, a normal direction of the contact surface VF is a direction along the axial direction of the tube 3. Therefore, the movable pin 5 is pushed into the tube 3 while the center axis of the movable pin 5 is maintained along the center axis of the tube 3.

A reaction force of the spring 8 generated when the movable pin 5 is pushed into the tube 3 is applied to the inclined surface 73 which is the other end portion of the movable body 7, and a force in a direction perpendicular to the axial direction of the tube 3 acts on the movable pin 5. Then, a part of a side surface of the movable body 7 is pressed against an inner wall of the tube 3 (arrow A1), the convex portion 71 that is the one end portion of the movable body 7 rolls on the planar portion 531 that is the rear end portion of the movable pin 5 (arrow A2), and the other part of the side surface of the movable body 7 is pressed against the inner wall of the tube 3 (arrow A3). This ensures the contact and conduction between the movable body 7 and the tube 3. The movable body 7 is reliably in contact with the movable pin 5. Therefore, it is possible to reliably ensure the conduction between the object 9 to be contacted and the tube 3.

According to the present embodiment, even if the contact between the movable pin 5 and the tube 3 becomes insufficient due to the shape of the tip end being the protruding end shape, the movable body 7 that comes into contact with the rear end portion (planar portion 531) of the movable pin 5 can be reliably brought into contact with the tube 3, and stable electrical connection between the movable pin 5 and the tube 3 can be realized via the movable body 7. Therefore, it is possible to provide a technique capable of improving contact stability in the spring connector 10 regardless of the shape of the tip end of the movable pin. As a result, a degree of freedom in design of the shape of the tip end of the movable pin is improved. In addition, it is possible to improve penetrability of an oxide film formed on the surface of the object to be contacted.

In the above-described embodiment, the spring connector 10 in which the movable pin 5 is provided on one end side of the tube 3 has been exemplified, but the present embodiment can be similarly applied to a spring connector having a configuration in which movable pins are provided on both end sides of the tube.

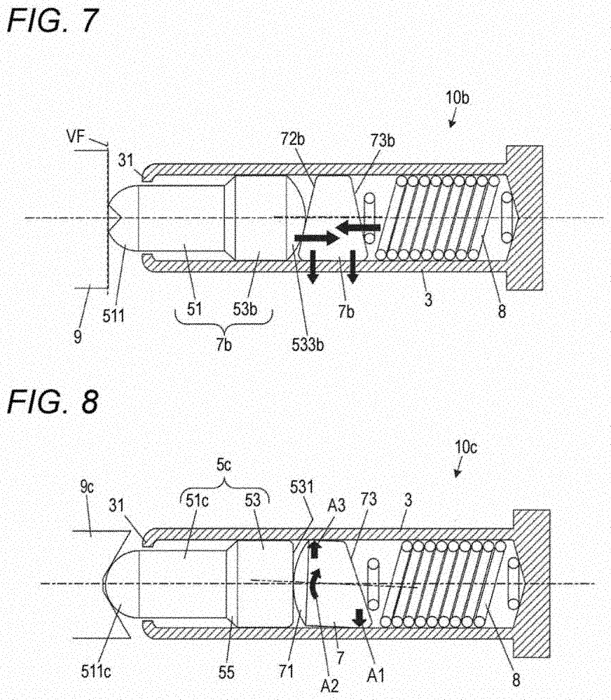

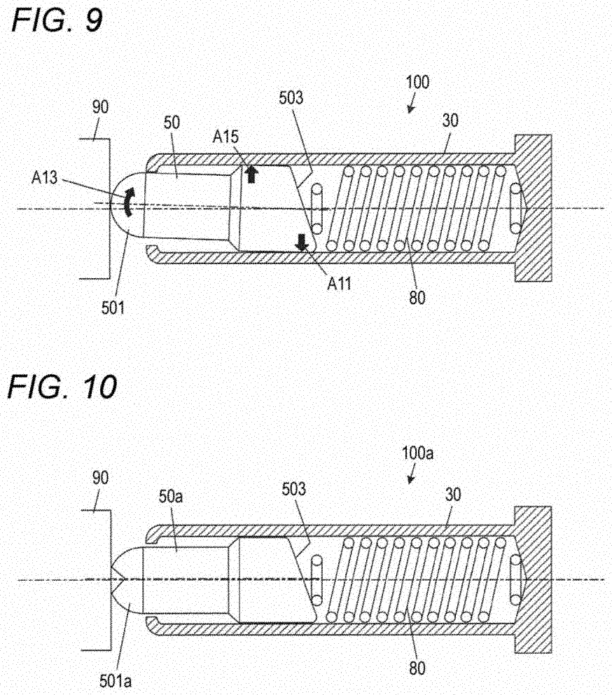

In the above-described embodiment, the case where the rear end portion of the movable pin 5 is formed as the planar portion 531 and the one end portion of the movable body 7 in contact with the planar portion 531 is formed as the convex portion 71 has been exemplified, but the rear end portion of the movable pin may be formed as a convex portion. FIG. 6 is a longitudinal sectional view showing a configuration example of a spring connector 10a according to a modified example, and FIG. 7 is a longitudinal sectional view showing a configuration example of a spring connector 10b according to other modified example.

For example, as shown in FIG. 6, the spring connector 10a may be configured such that a rear end of a large diameter portion 53a, which is a rear end portion of a movable pin 5a, is formed as a convex portion 533a, and one end portion of a movable body 7a is formed as a flat planar portion 72a. According to this configuration as well, the same effects as those of the above-described embodiment can be achieved.

As shown in FIG. 7, the spring connector 10b may be configured such that a rear end of a large diameter portion 53b, which is a rear end portion of a movable pin 5b, is formed as a convex portion 533b, and both end portions of the movable body 7b are formed as inclined surfaces 72b, 73b inclined with respect to the axial direction of the tube 3. More specifically, in FIG. 7, the movable body 7b is formed in a symmetrical shape having a trapezoidal shape in a side view, so that both one end portion in contact with the rear end portion of the movable pin 5b and the other end portion urged by the spring 8 are the inclined surfaces 72b, 73b. In this configuration, although inclination of the movable body 7b does not occur, the movable body 7b is pressed against one side surface of the tube 3 as indicated by arrows in FIG. 7, and the contact and conduction between the movable body 7b and the tube 3 are ensured. Therefore, the movable body 7b that comes into contact with the rear end portion (convex portion 533b) of the movable pin 5b can be reliably brought into contact with the tube 3, and the same effects as those of the above-described embodiment can be achieved. In addition, since both the one end portion and the other end portion of the movable body 7b are inclined surfaces, when the movable body 7b is inserted into the tube 3 at the time of manufacturing, it is not necessary to be aware of an orientation of the movable body 7b. In FIG. 7, both the inclined surfaces of the one end portion and the other end portion of the movable body 7b are made non-parallel to each other and have a symmetrical shape of a trapezoidal shape in a side view, but a movable body in which both the inclined surfaces of the one end portion and the other end portion are made parallel to each other and have a parallelogram shape in a side view may be adopted.

The spring connector may be configured such that both the rear end portion of the movable pin and the one end portion of the movable body are formed as convex portions.

In the above-described embodiment, the case where the shape of the tip end portion of the movable pin is the protruding end shape having the plurality of protrusions has been exemplified, but the present invention can also be applied to other shapes. FIG. 8 is a longitudinal sectional view showing a configuration example of a spring connector 10c according to a modified example. In the spring connector 10c of the present modified example, a tip end portion 511c of a movable pin 5c (the tip end of the small diameter portion 51c) has a hemispherical shape. As shown in FIG. 8, a contact surface of an object 9c to be contacted has a recessed concave shape such as a conical shape or a curved shape. In this case, when the object 9c to be contacted is pressed against the movable pin 5c during use, the hemispherical tip end portion 511c is fitted into the recess, and the movable pin 5c is pushed into the tube 3 while a center axis of the movable pin 5c is maintained along the center axis of the tube 3. Therefore, the movable body 7 moves as shown by arrows A1 to A3 in the same manner as described in the above-described embodiment, and the contact and conduction between the movable body 7 and the tube 3 are ensured. Therefore, the same effects as those of the above-described embodiment can be achieved.

Several embodiments and modified examples thereof have been described. The disclosure of the present specification can be summarized as follows.

According to an aspect of the present disclosure, a spring connector includes: a conductive tube; a movable pin that has a tip end portion protruding from an opening of the tube along an axial direction of the tube; a movable body that is provided inside the tube and that has one end portion in contact with a rear end portion of the movable pin; and a spring that is provided inside the tube and that is configured to urge another end portion of the movable body in a direction in which the movable pin protrudes. The other end portion of the movable body is an inclined surface inclined with respect to the axial direction, and at least one of the one end portion of the movable body and the rear end portion of the movable pin includes a convex portion.

According to this aspect, the movable body is interposed between the movable pin and the spring, the one end portion of the movable body is brought into contact with the rear end portion of the movable pin, and the other end portion of the movable body is urged by the spring in the direction in which the movable pin protrudes. The other end portion of the movable body is the inclined surface inclined with respect to the axial direction of the tube, and at least one of the one end portion of the movable body and the rear end portion of the movable pin has the convex portion. According to this, when the movable pin is pushed into the tube, the movable body is inclined, and the side surface of the movable body is pressed against the inner wall of the tube. Therefore, the movable body and the tube can be reliably brought into contact with each other during use, and stable electrical connection between the movable pin and the tube can be realized via the movable body. Therefore, it is possible to provide the technique capable of improving the contact stability in the spring connector regardless of the shape of the tip end of the movable pin.

The tip end portion of the movable pin may have a protruding end shape forming a virtual contact surface that is to come into surface contact with an object to be contacted, and a normal direction of the contact surface may be a direction along the axial direction.

The protruding end shape may include two or more protrusions.

The protruding end shape may include a line-shaped edge.

The convex portion may have a curved shape.

The one end portion of the movable body may be the convex portion, and the rear end portion of the movable pin may be a planar portion.

The rear end portion of the movable pin may be the convex portion, and the one end portion of the movable body may be an inclined surface inclined with respect to the axial direction.

### REFERENCE SIGNS LIST

10, 10a, 10b, 10c spring connector

3 tube

31 locking portion

5, 5a, 5b, 5c movable pin

51, 51c small diameter portion

511, 511a, 511b, 511c tip end portion

513 edge

53, 53a, 53b large diameter portion

531 planar portion

533a, 533b convex portion

55 step surface

7, 7a, 7b movable body

71 convex portion

72a planar portion

73 inclined surface

72b, 73b inclined surface

8 spring

VF contact surface

9 object to be contacted

1. A spring connector comprising:
a conductive tube;
a movable pin that has a tip end portion protruding from an opening of the tube along an axial direction of the tube;
a movable body that is provided inside the tube and that has one end portion in contact with a rear end portion of the movable pin; and
a spring that is provided inside the tube and that is configured to urge another end portion of the movable body in a direction in which the movable pin protrudes,
wherein the other end portion of the movable body is an inclined surface inclined with respect to the axial direction, and
wherein at least one of the one end portion of the movable body and the rear end portion of the movable pin includes a convex portion.

2. The spring connector according to claim 1,
wherein the tip end portion of the movable pin has a protruding end shape forming a virtual contact surface that is to come into surface contact with an object to be contacted, and,
wherein a normal direction of the contact surface is a direction along the axial direction.

3. The spring connector according to claim 2,
wherein the protruding end shape includes two or more protrusions.

4. The spring connector according to claim 2,
wherein the protruding end shape includes a line-shaped edge.

5. The spring connector according to claim 1,
wherein the convex portion has a curved shape.

6. The spring connector according to claim 1,
wherein the one end portion of the movable body is the convex portion, and
wherein the rear end portion of the movable pin is a planar portion.

7. The spring connector according to claim 1,
wherein the rear end portion of the movable pin is the convex portion, and
wherein the one end portion of the movable body is an inclined surface inclined with respect to the axial direction.
